(19) United States
(12) Patent Application Publication
(10) Pub. No.: US 2018/0333895 A1
(43) Pub. Date: Nov. 22, 2018

(54) CUTTING BLADE DETECTING MECHANISM FOR CUTTING APPARATUS

(71) Applicant: DISCO CORPORATION, Tokyo (JP)

(72) Inventors: Satoshi Sawaki, Tokyo (JP); Ken Uehara, Tokyo (JP); Tsuyoshi Kasai, Tokyo (JP)

(21) Appl. No.: 15/985,844

(22) Filed: May 22, 2018

(30) Foreign Application Priority Data
May 22, 2017 (JP) 2017-100492

(51) Int. Cl. B28D 5/00; H01L 21/687; B28D 5/02; H01L 21/67

(52) U.S. Cl. CPC B28D 5/0064; H01L 21/67092; B28D 5/024; H01L 21/68764

(57) ABSTRACT

A cutting blade detecting mechanism is provided in a cutting apparatus including a chuck table for holding a workpiece and a cutting blade having an annular cutting edge for cutting the workpiece held on the chuck table while the workpiece is being cutting-fed in an X-axis direction. The cutting blade detecting mechanism has a blade detecting unit configured to detect the state of the cutting edge of the cutting blade. The blade detecting unit includes an image capturing unit configured to capture an image of the cutting edge in the X-axis direction, a light emitter disposed in a position opposite the image capturing unit and facing the cutting edge, and a decision unit configured to determine the state of the shape of a tip end of the cutting edge from the image of the cutting edge which has been captured by the image capturing unit.

### BACKGROUND OF THE INVENTION

### Field of the Invention

The present invention relates to a catting blade detecting mechanism for use in a cutting apparatus.

### Description of the Related Art

Workplaces with a plurality of devices such as Integrated circuits (ICs), large-scale integration (LSI) circuits, etc. formed on their face sides are ground on their reverse sides to a predetermined thickness, and then divided toy a processing apparatus such as a dicing apparatus or the like into individual devices, which will be used in electronic apparatuses such as mobile phones, personal computers, etc. Devices on workplaces are packaged by a technology called quad flat nonleaded (QFN) packaging, for example. Packaged substrates fabricated by the QFN packaging are divided into individual devices by a rotating disk-shaped cutting blade in a dicing step that follows a packaging resin encapsulating step,

When a cutting blade cuts packaged substrates, the cutting blade is unevenly worn with its tip end worn irregularly. As the uneven wear develops on the cutting blade, the unevenly worn tip end of the cutting blade leaves a flaring shaped mark on package side surfaces at a certain stage during the process of dividing packaged substrates, possibly producing oversized defective packages. Therefore, it is necessary to perform dicing on packaged substrates with a cutting blade while the operator is confirming the state of wear on the tip end of the cutting blade. Even if a cutting blade has not been unevenly worn to the extent that it brings out defective products, since cutting blades gradually lose their sharpness by repeating cutting sessions, it is desirable for the operator to recognise a proper timing to replace cutting blades that have become blunt due to wear.

There has been proposed a cutting apparatus having a test material to be cut by a cutting blade for presenting its cut state for an examination to see how much the cutting blade has been worn, and observing means for observing the cutting quality of the cutting blade that is transferred to the test material, so that the cutting blade can be checked for its wear and it can be decided whether the cutting blade should be replaced or not (see, for example, Japanese Patent Laid-open No. 2007-296604).

### SUMMARY OF THE INVENTION

Existing cutting blade detecting mechanisms are problematic in that they need to temporarily stop a product processing operation in order to examine cutting blades for their wear, resulting in product processing down time.

It is therefore an object of the present invention to provide a cutting blade detecting mechanism for cutting apparatus which is capable of detecting the state of a cutting blade quickly and highly accurately compared to conventional cutting blade detecting mechanisms.

In accordance with an aspect of the present invention, there is provided a cutting blade detecting mechanism for use in a cutting apparatus including a chuck table for holding a workpiece thereon and cutting means Including a cutting blade having an annular cutting edge for cutting the workpiece held on the chuck table while the workpiece is being cutting-fed in an X-axis direction, the cutting blade detecting mechanism having blade detecting means for detecting the state of the cutting edge of the cutting blade. The blade detecting means includes an image capturing milt configured to capture an image of an outer: periphery including an outer periphery end of the cutting edge in the X-axis direction, a light emitter disposed in a position opposite the image capturing unit and facing the cutting edge, and a decision unit configured to determine the state of the shape of a tip end of the cutting edge from the image of the outer periphery of the cutting edge which has been captured by the image capturing unit.

In the cutting blade detecting mechanism according to the present invention, the image capturing unit captures an image of the outer periphery including the outer periphery end of the cutting edge in the X-axis direction which is a cutting feed direction, and the decision unit determines the state of the shape of the tip end of the cutting edge from the image of the outer periphery of the cutting edge. The shape of the tip end of the cutting edge can be detected highly accurately while the cutting apparatus is suffering minimum down time.

The cutting blade detecting mechanism according to the present invention is thus capable of detecting the state of the cutting blade quickly and highly accurately compared to conventional cutting blade detecting mechanisms.

The above and other objects, features and advantages of the present invention and the manner of realizing them will become more apparent, and the invention itself will best be understood from a study of the following description and appended claim with reference to the attached drawings showing some preferred embodiments of the invention.

### BRIEF DESCRIPTION OF THE DRAWINGS

FIG. 1 is a perspective view of a cutting apparatus incorporating a cutting blade detecting mechanism according to the present invention;

FIG. 2 is a perspective view of cutting means of the cutting apparatus;

FIG. 3 is a side elevational view of a cutting blade detecting mechanism according to a first embodiment of the present invention;

FIG. 4 is a side elevational view of a cutting blade detecting mechanism according to a second embodiment of the present invention;

FIG. 5 is a diagram showing by way of example an image of an outer peripheral portion of a cutting edge in its initial good state, the image being captured by an image capturing unit;

FIG. 6 is a diagram showing by way of example an image of an outer peripheral portion of the cutting edge in a worn state, the image being captured by the image capturing unit.

### DETAILED DESCRIPTION OF THE PREFERRED EMBODIMENTS

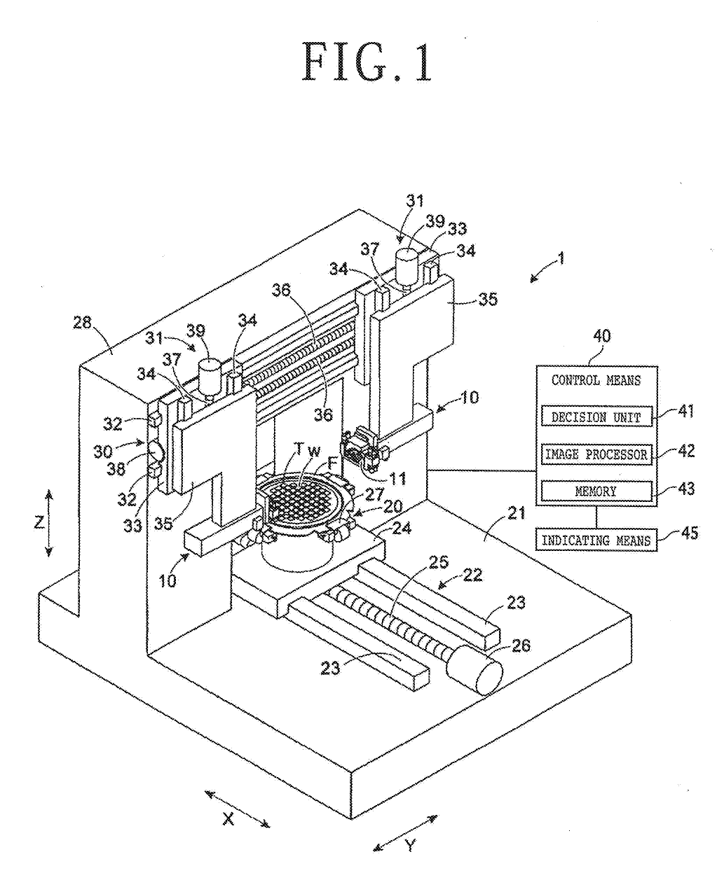

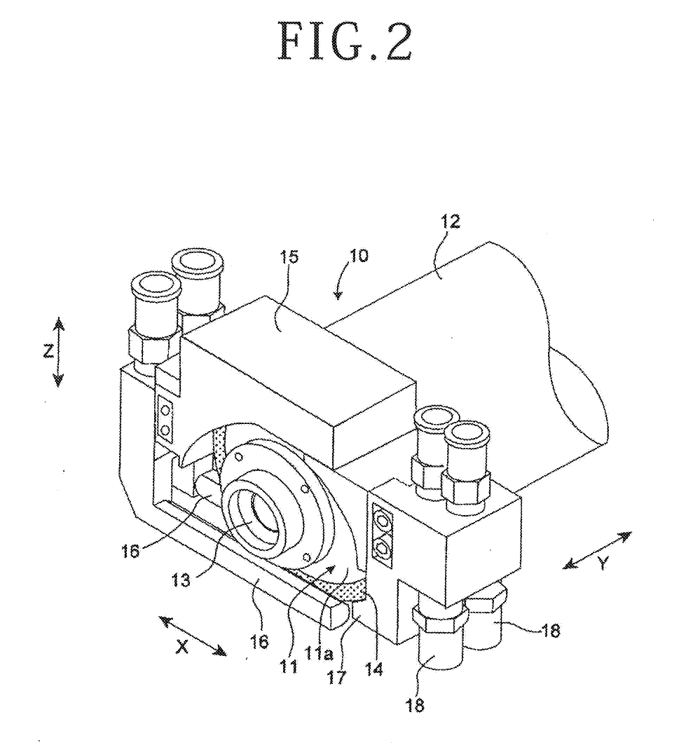

Preferred embodiments of the present invention will be described below with reference to the accompanying drawings. FIG. 1 is a perspective view of a cutting apparatus incorporating a cutting blade detecting mechanism according to the present invention. FIG. 2 is a perspective view of cutting means of the cutting apparatus. The cutting apparatus and the cutting means are not limited to the structural details shown in FIGS. 1 and 2, but may be of any structure insofar as they are capable of cutting workplaces with a cutting blade.

As shown in FIGS. 1 and 2, a cutting apparatus 1 includes a pair of cutting means 10 each having a cutting blade 11 of standards corresponding to a workpiece W. The cutting apparatus 1 is arranged to move the cutting blades 11 and the workpiece W held on a chuck table 20 relatively to each other for cutting the workpiece W on the chuck table 20 along a grid of projected dicing lines thereon with the cutting blades 11. The workpiece W has a face side demarcated by the projected dicing lines into a plurality areas with various devices formed therein.

As shown in FIG. 1, the workpiece W has a reverse side with a dicing tape T stuck thereto, and a ring frame F is stuck to the outer periphery of the dicing tape T. The workpiece W that is supported on the ring frame F by the dicing tape T is loaded from an external device into the cutting apparatus 1 by transport means which is omitted from illustration in FIG. 1.

As shown in FIG. 1, the cutting apparatus 1 includes a base 21 on which there is mounted cutting feed means 22 for cutting-feeding the chuck table 20 in X-axis directions. The cutting feed means 22 includes a pair of parallel guide rails 23 disposed on an upper surface of the base 21 and extending in the X-axis directions and a motor-driven X-axis table 24 slidably mounted on the guide rails 23. The chuck table 20 is supported on the X-axis table 24. The X-axis table 24 has a nut unit, not shown, disposed on a lower reverse side thereof and threaded over a ball screw 25 disposed between the guide rails 23. The ball screw 25 has an end coupled to an electric drive motor 26. When the electric drive motor 26 is energized to rotate the ball screw 25 about its own axis, the X-axis table 24 and hence the chuck table 20 are cutting-fed in the X-axis directions along the guide rails 23.

The chuck table 20 that holds the workpiece W thereon is mounted on the X-axis table 24 for rotation about a Z axis that is shown as a vertical axis perpendicular to the X-axis directions in FIG. 1. The chuck table 20 includes a holding surface, not shown, as an upper surface thereof, made of a porous ceramics material, and holds the workpiece W under suction on the holding surface by a negative pressure acting through the holding surface on the workpiece W. Four clamps 27 are disposed on the periphery of the chuck table 20 around the holding surface for gripping and securing the ring frame F around the workpiece W to the chuck table 20. An upright portal-shaped column 28 is mounted on an upper surface of the base 21 across and over the guide rails 23, i.e., the track along which the chuck table 20 moves in the X-axis directions.

The column 28 supports thereon indexing feed means 30 for indexing-feeding the cutting means 10 in Y-axis directions, which, are perpendicular to the X-axis directions and the 2-axis directions, and a pair of incising feed means 31 for incising-feeding the cutting means 10 in the 2-axis directions. The indexing feed means 30 includes a pair of parallel guide rails 32 disposed on a front surface of the column 28 and extending in the Y-axis directions and a pair of Y-axis tables 33 slidably mounted on the guide rails 32. Each piece of the incising feed means 31 includes a pair of parallel guide rails 34 disposed on one of the Y-axis tables 33 and extending in the Z-axis directions and a Z-axis table 35 slidably mounted on the guide rails 34.

The cutting means 10 are mounted on the lower ends of the Z-axis tables 35. The Y-axis tables 33 and the Z-axis tables 35 have respective, nut units, not shown, disposed on reverse sides thereof and threaded over ball screws 36 and 37 disposed between the guide rails 32 and 34. The ball screws 36 on the Y-axis tables 33 and the ball screws 37 on the Z-axis tables 35 have ends coupled to electric drive motors 38 and 39. When the electric drive motors 38 are energized to rotate the ball screws 36 about their own axes, the Y-axis tables 33 and hence the cutting means 10 are indexing-fed in the Y-axis directions along the guide rails 32. When the electric drive motors 39 are energized to rotate the ball screws 37 about their own axes, the Z-axis tables 35 and hence the cutting means 10 are incising-fed in the Z-axis directions along the guide rails 34.

The cutting means 10 are paired in respective positions spaced from each other along the Y-axis directions. Since the cutting means 10 are essentially identical in structure to each other, one of the cutting means 10 will be described below. The present invention is also applicable to a cutting apparatus which includes a single piece of cutting means 10.

As shown in FIG. 2, the cutting means 10 has a spindle 13 rotatably supported in a housing 12, and the cutting blade 11 is mounted on a distal end of the spindle 13. The cutting blade 11 has a hub base 11a fixed to the spindle 13 and an annular cutting edge 14 made of abrasive grains of diamond bound by a binder and fixed to the outer periphery of the hub base 11a.

The cutting means 10 also includes a box-shaped blade cover 15 disposed partly around the cutting blade 11 to cover the same, except a lower portion of the cutting blade 11 that projects downwardly. A pair of substantially L-shaped side nozzles 16 extend from one side of the blade cover 15 in the X-axis directions and are disposed one on each side of the cutting blade 11. The side nozzles 16 eject cleaning water sideways toward the cutting blade 11 in the Y-axis directions. A shower nozzle 17 and a pair of front nozzles 18 are disposed on the other side of the blade cover 15 in the X-axis directions. The shower nozzle 17 ejects cleaning water toward the cutting blade 11 in one of the X-axis directions. The front nozzles 18 eject cleaning water toward the workpiece W (see FIG. 1) in one of the Z-axis directions, i.e., in a downward direction.

The cutting apparatus 1 Includes control means 40 (see FIG. 1) for controlling various components of the cutting apparatus 1. The control means 40 controls operation of the cutting means 10, the chuck table 20, the cutting feed means 22, the indexing feed means 30, and the incising feed means 31.

For cutting the workpiece W on the cutting apparatus 1 which is constructed as described above, the workpiece W that is held on the chuck table 20 is loaded into a processing area where the workpiece W can be processed by the cutting means 10. In FIG. 1, the workpiece W is illustrated as having been loaded Into the processing area. The indexing feed means 30 is actuated to position the cutting edge 14 of the cutting blade 11 over one of the uncut projected dicing lines on the workpiece W in positional alignment therewith. Then, the cutting blade 11 is rotated about its own axis by the spindle 13, and the incising feed means 31 is actuated to lower the cutting means 10 to a predetermined incising depth along the Z-axis directions. The cutting feed means 22 is actuated to move the workpiece W in one of the X-axis directions to cause the cutting edge 14 of the cutting blade 11 to cut the workpiece W along the projected dicing line that is aligned with the cutting edge 14.

When the cutting of the workpiece W along the projected dicing line is over, the indexing feed means 30 is actuated to move the cutting means 10 in one of the Y-axis directions until the cutting edge 14 of the cutting blade 11 over a next uncut projected dicing line in positional alignment therewith. Then, the cutting means 10 cuts the workpiece W along the projected dicing line in the same manner as described above. When the workpiece W has been cut along all the projected dicing lines that are arrayed in the Y-axis directions, the chuck table 20 is turned 90 degrees about the 2 axis along the 2-axis directions, orienting uncut projected dicing lines on the workpiece W parallel to the Y-axis directions. Then, the cutting means 10 cuts the workpiece W along all the uncut projected dicing lines that are arrayed in the Y-axis directions. The workpiece W has now been cut along all the projected dicing lines in the grid pattern, and divided into individual devices demarcated by the projected dicing lines. The workpiece W thus cut is unloaded from the processing area, whereupon the cutting process of the cutting apparatus 1 is finished.

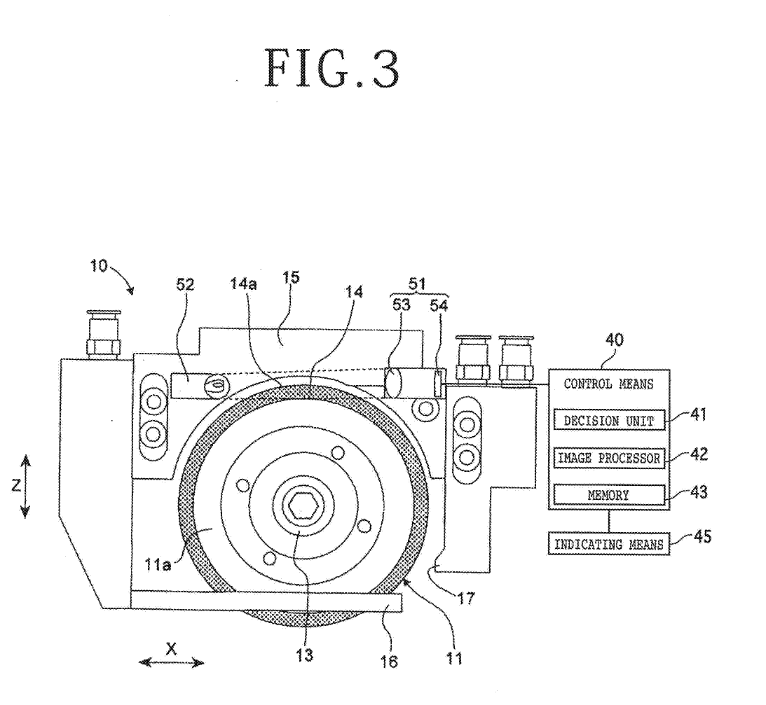

When the cutting process described above is repeated, the cutting edge 14 of the cutting blade 11 is worn. The cutting apparatus 1 includes a cutting blade detecting mechanism having blade detecting means for detecting the state of the cutting edge 14. Details of cutting blade detecting mechanisms according to different embodiments of the present invention will be described below with reference to FIGS. 3 through 6.

FIG. 3 shows a cutting blade detecting mechanism according to a first embodiment of the present invention. The cutting blade detecting mechanism shown in .FIG. 3 has blade detecting means including an image capturing unit 51 and a light emitter 52 which are disposed in the blade cover 15 of the cutting means 10, and a decision unit 41 included as a function of the control means 40.

The image capturing unit 51 includes an image capturing optical system (lens system) 53 capable of focusing an optical image of a subject and an image capturing element 54 for detecting the optical image focused by the image capturing optical system 53. The image capturing element 54 generates an image signal from the optical image produced by the image capturing optical system 53 by way of photoelectric conversion and sends the image signal to the control means 40. The control means 40 includes, in addition to the decision unit 41, an image processor 42 for processing the image signal sent from the image capturing element 54 to generate image data of the subject, and a memory 43 for storing the image data from the image processor 42.

As shown in FIG. 3, the image capturing unit 51 is positioned on a line tangential to the cutting edge 14 of the cutting blade 11 parallel to the X-axis directions. More specifically, the image capturing optical system 53 of the image capturing unit 51 has its optical axis oriented generally along the X-axis directions and positioned at substantially the same height as an upper margin of the cutting edge 14 in the Z-axis directions and in substantially the same position as the cutting edge 14 in the Y-axis directions. Therefore, the image capturing unit 51 can capture an image of the outer periphery of the cutting edge 14 which includes an outer periphery end 14a thereof along the X-axis directions.

As shown in FIG. 3, the light emitter 52 is positioned opposite the image capturing unit 51 across the outer periphery of the cutting edge 14 of the cutting blade 11 along the X-axis directions. The light emitter 52 includes a light source such as a light emitting diode (LED) or the like and a light projector for projecting light emitted by the light source toward the image capturing unit 51 that faces the light projector along the X-axis directions.

Providing the cutting edge 14 of the cutting blade 11 is observed from the image capturing unit 51 along the X-axis directions, the cutting edge 14 is positioned in front and the light emitter 52 is positioned behind the cutting edge 14 in the observational viewing field of the image capturing unit 51. When the light emitter 52 is energized, it illuminates the observational viewing field, making it possible for the image capturing unit 51 to capture an image of the outer periphery of the cutting edge 14. The state of the cutting edge 14 is detected on the basis of the captured image.

As shown In FIG. 3, the image capturing unit 51 and the light emitter 52 are provided in respective positions that do not protrude largely in the X-axis directions from the range of the diameter of the cutting blade 11, i.e., in respective positions close to the cutting edge 14. Therefore, the cutting means 10 does not need to be unduly increased in size in the X-axis directions, but the image capturing unit 51 and the light emitter 52 are disposed with good space efficiency so as to be neatly housed in the blade cover 15. Since the image capturing unit 51 is positioned closely to the cutting edge 14, it can capture a highly accurate image of the cutting edge 14 from a position close thereto. Furthermore, since the light emitter 52 is also positioned closely to the cutting edge 14, it can illuminate the cutting edge 14 efficiently without delivering stray light to surrounding areas.

The image capturing unit 51 and the light emitter 52 are provided in respective positions where they do not obstruct water ejected from the side nozzles 16, the shower nozzle 17, and the front nozzles 18, and hence do not adversely affect the Cutting process performed by the cutting means 10.

In a stage prior to detecting the state of the cutting edge 14 of the cutting blade 11, the image capturing unit 51 captures an image of the shape of the outer periphery of the cutting edge 14 which is in a good state not yet worn, and stores its image data in the memory 43. The image data thus stored represents a reference image to be referred to later. For example, the state of the cutting edge 14 immediately after its shape has been corrected by truing (making it into a true circle) and it has been unclogged by dressing may be used as a timing to capture a reference image.

For inspecting the state of the cutting edge 14 after the cutting blade 11 has been in service for some time, the image capturing unit 51 captures an image of the shape of the outer periphery of the cutting edge 14. It is desirable that image capturing conditions at this time should match those for acquiring a reference image. The decision unit 41 then compares the image of the outer periphery of the cutting edge 14 that has been in service and the image of the outer periphery of the cutting edge 14 in a good state that is stored in the memory 43 with each other, and decides whether the cutting edge 14 is still kept in a good state or not.

The image capturing unit 51 captures images of the outer periphery of the cutting edge 14 and the decision unit 41 makes a decision at a designated frequency while the cutting apparatus 1 is operating in a fully automatic mode. Specifically, the designated frequency may cover times including a time after the cutting blade 11 has been set up and its original position has been established.

While the cutting apparatus 1 is operating in the fully automatic mode, the image capturing unit 51 captures images of the outer periphery of the cutting edge 14 at the time the spindle 13 is rotating. In order to capture clear images of the cutting edge 14 along its full circumference even when the spindle 13 is rotating, appropriate timings are established for the light emitter 52 to emit light and for the image capturing unit 51 to capture images. Specifically, in a single image capturing session, the image capturing unit 51 can capture an image of a partial area of the cutting edge 14 in the direction in which the cutting blade 11 rotates. The number of times that the image capturing unit 51 has to capture images in order to cover the entire circumference of the cutting edge 14 and the timings at which the image capturing unit 51 has to capture such images can be calculated on the basis of conditions which include the number of revolutions of the cutting blade 11 per unit time, the circumferential length of the cutting edge 14 in the direction in which the cutting blade 11 rotates, and an angular range of the cutting edge 14 whose image can be captured by the image capturing unit 51 per image capturing session. The light emitter 52 may emit light intermittently, i.e., may emit blinking light, in synchronism with the timings at which the image capturing unit 51 captures images, or may emit light at all times and a shutter in the image, capturing unit 51 may be selectively opened and closed to control the light applied from the light emitter 52 to the image capturing unit 51.

In order to capture clear images of the cutting edge 14 along its full circumference when the spindle 13 is in rotation, the image processor 42 binarizes images captured by the image capturing unit 51. The binarized images provide a sharp contrast between image areas where light emitted from the light emitter 52 has been blocked by the cutting blade 11 and image areas where light emitted from the light emitter 52 has reached the Image capturing unit 51 without being obstructed by the cutting blade 11, so that the decision unit 41 can decide how much the cutting edge 14 has been worn with increased accuracy and at an increased processing speed.

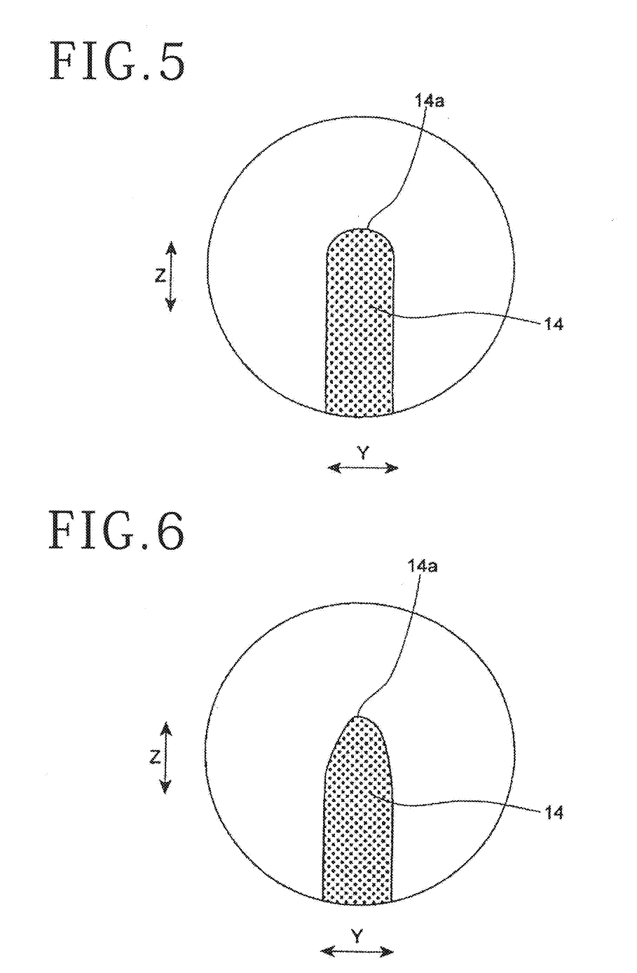

FIG. 5 shows by way of example an image of an outer peripheral portion of the cutting edge 14 in its initial good state, the image being captured as a reference image by the image capturing unit 51. FIG. 6 shows by way of example an image of an outer peripheral portion of the cutting edge 14 which has been worn in use, the image being captured by the image capturing unit 51. As can be understood from a comparison with the reference image shown in FIG. 5, the image shown in FIG. 6 indicates that the outer periphery end 14a of the cutting edge 14 is unevenly worn with a corner, where one of the Y-axis directions and one of the Z-axis directions cross each other, largely worn off. If the cutting blade 11 continues to be used despite the uneven wear, then the unevenly worn cutting edge 14 may not cut the workpiece W (see FIG. 1) properly, but may form flaring protrusions on side surfaces of devices divided from the workpiece W or may give rise to a failure to divide the workpiece W into devices.

The decision unit 41 detects the current state of the cutting edge 14 from the comparison of the images shown in FIGS. 5 and 6 and decides whether the cutting edge 14 is in a proper state or not. The decision unit 41 may compare the images according to various standards. For example, the decision unit 41 may determine the overall similarity of images according to template matching, or may extract and compare features of images according to Hough transform. Mot only the state of the outer periphery end 14a of the cutting edge 14, but also the state of side surfaces of the cutting edge 14 in the Y-axis directions may be inspected on the basis of images captured in the X-axis directions.

If the decision unit 41 decides that the cutting edge 14 is not in a good state because of uneven wear or the like, then the control means 40 performs a predetermined process. For example, the control means 40 indicates an error through indicating means 45 (see FIGS. 1 and 3) to the operator who is operating the cutting apparatus 1. The error may be indicated by the indicating means 45 as a warning displayed on a control panel that the operator is operating, a turning-on of a warning lamp on the cutting apparatus 1, a warning sound from a speaker, or any of various other warning patterns. When the cutting edge 14 has been detected as not being in a good state, if the operator instructs the cutting apparatus 1 to start a cutting process, the control means 40 may abort the cutting process.

The accuracy with which the state of the cutting edge 14 is detected is affected by the quality of images acquired by the image capturing unit 51. In order for the decision unit 41 to clearly recognize the state of the cutting edge 14 based on images acquired by the image capturing unit 51, the images are required to be clear focused images. The image capturing unit 51 can acquire a clear focused image in one image capturing session only when it is captured within the depth of field of the image capturing optical system 53 in the X-axis directions. Any images captured outside of the depth of field of the image capturing optical system 53 are not clear. Therefore, the image capturing unit 51 has a focusing function for adjusting the focus of the image capturing optical system 53, and captures an image covering a subject, area in its entirety while adjusting the focus in the X-axis directions, or stated otherwise, captures an image that is fully focused in its entirety in the X-axis directions, so that the state of the cutting edge 14 can be recognized highly accurately in a wide range in the X-axis directions based on the image. As can be understood from FIG. 3, while the cutting blade 11 is not rotating, the image capturing unit 51 that is positioned on the line tangential to the cutting edge 14 parallel to the X-axis directions can capture an image of a partial area of the cutting edge 14 in a single image capturing session, as described above. Therefore, the cutting blade 11 is rotated to cause successive partial areas of the cutting edge 14 to appear in the field of vision of the image capturing unit 51. The decision unit 41 can detect the state of the cutting edge 14 along the entire periphery of the cutting blade 11 based on images captured by the image capturing unit 51 of those successive partial areas of the cutting edge 14.

Providing the images of the outer periphery of the cutting edge 14 are of a higher magnification, minute changes in the shape of the cutting edge 14 can be detected with higher accuracy. Therefore, the image capturing optical system 53 may have a function to change the image capturing magnification, i.e., a zooming function, so that the image capturing unit 51 can capture images at different magnifications. The higher the magnification is, the higher the accuracy with which to detect changes in the shape of the cutting edge 14 is, but the smaller the image capturing range becomes. If images of all partial areas of the cutting edge 14 are captured at a maximum magnification, then the period of time required to examine the cutting edge 14 tends to be long. In view of this shortcoming, the control means 40 may control the image capturing unit 51 to capture images of the cutting edge 14 at a lower magnification to grasp the entire state of the outer periphery of the cutting edge 14, and then capture images of particular areas of the outer periphery end 14a of the cutting edge 14 at a higher magnification to detect slight changes in the worn state of the cutting edge 14.

The image capturing unit 51 may capture moving images of the cutting edge 14 as well as still images thereof. When the image capturing unit 51 captures moving images of the cutting edge 14 while the cutting blade 11 is rotating, the control means 40 can detect, how much the cutting edge 14 fluctuates in the Y-axis directions and the Z-axis directions in addition to changes in the shape of the cutting edge 14 as described above.

Inasmuch as the cutting blade detecting mechanism detects the state of the cutting edge 14 through an optical observation of the cutting edge 14 without mechanical contact therewith, it can detect the state of the cutting edge 14 efficiently while the cutting means 10 is in operation without stopping a product processing operation of the cutting apparatus 1, i.e., without stopping the fully automatic mode of operation of the cutting apparatus 1. The cutting blade detecting mechanism can detect the state of the cutting edge 14 at any desired timings that are selected. After the cutting blade 11 has been set up, as described above, the state of the cutting edge 14 can be detected efficiently without wasting time.

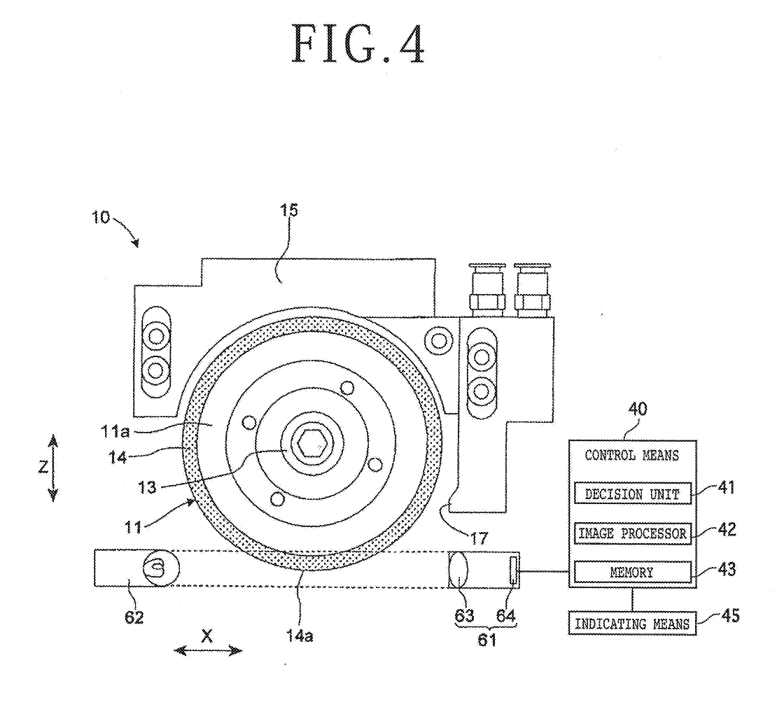

FIG. 4 shows a cutting blade detecting mechanism according to a second embodiment of the present invention. Those parts of the cutting blade detecting mechanism according to the second embodiment which are identical to those according to the first embodiment are denoted by identical reference characters, and will not be described in detail below. The cutting blade detecting mechanism shown in FIG. 4 captures images of the outer periphery of the cutting edge 14 at a lower margin thereof in the Z-axis directions, in the X-axis directions. The cutting blade detecting mechanism includes an image capturing unit 61 and a light emitter 62, and the image capturing unit 61 includes an image capturing optical system 63 and an image capturing element 64. The image capturing unit 61 including the image capturing optical system 63 and the image capturing element 64, and the light emitter 62 are identical in structure to the image capturing unit 51 including the image capturing optical system 53 and the image capturing element 54, and the light emitter 52 according to the first embodiment except for the positions in the Z-axis directions. In FIG. 4, the side nozzles 16 (see FIGS. 2 and 3) are omitted from illustration for making the image capturing unit 61 and the light emitter 62 easier to see. The capturing unit 61 and the light emitter 62 are actually positioned out of physical interference with the side nozzles 16. In the images of the outer periphery of the cutting edge 14 that are acquired by the image capturing unit 61, the outer periphery end 14a of the cutting edge 14 is directed downwardly unlike that shown in FIGS. 5 and 6.

In the first and second embodiments described above, images of the cutting edge 14 of the cutting blade 11 are captured in the X-axis directions along which the chuck table 20 is cutting-fed by the cutting feed means 22. Consequently, the shape of both sides of the outer cutting edge 14 in the Y-axis directions, in particular, of the periphery end 14a can be detected highly accurately. If images of the outer periphery of the cutting edge 14 are captured in the Y-axis directions unlike images captured in the embodiments of the present invention, then though an amount of wear on the cutting blade 11 in the Z-axis directions, i.e., the diametrical directions of the cutting blade 11, can be detected from the captured images, irregular wear on the cutting blade 11 in the Y-axis directions, i.e., the widthwise directions of the cutting blade 11, is difficult to recognize from the captured images. According to the embodiments of the present invention, it is possible to determine the state of wear on both sides of the cutting edge 14 in the Y-axis directions in addition to the state of wear on the cutting edge 14 in the Z-axis directions, as shown in FIG. 6. Since the shape of both sides of the outer periphery end 14a of the cutting edge 14 in the Y-axis directions greatly affects the accuracy of the cutting process on the workpiece W, examining the shape of the cutting edge 14 with either one of the cutting blade detecting mechanisms is effective to increase the quality of the cutting process performed by the cutting apparatus 1. The cutting blade detecting mechanisms according to the embodiments of the present invention are of excellent operation efficiency as they can detect the shape of the cutting edge 14 without giving rise to product processing down time.

In the above embodiments, the cutting blade 11 is illustrated as a hub blade in which the cutting edge 14 is fixed to the hub base 11a. However, the cutting blade 11 is not limited to such a hub blade, but may be a hubless washer blade. The chuck table 20 is not limited to a suction-chuck table, but may be an electrostatic-chuck table. The cutting process performed by the cutting blade 11 is not limited to a process of dividing a workpiece along projected dicing lines thereon, but may be a process of trimming a workpiece edge by cutting it off.

Workpieces that can be processed by the cutting apparatus 1 include semiconductor device wafers, optical device wafers, packaged substrates, semiconductor substrates, inorganic material substrates, oxide wafers, raw ceramics wafers, piezoelectric substrates, and various other workpieces, for example. Semiconductor device wafers may be silicon wafers or compound semiconductor wafers with devices formed thereon. Optical device wafers may be sapphire wafers or silicon carbide wafers with devices formed thereon. Packaged substrates may be chip size package (CSP) substrates. Semiconductor substrates may be made of silicon, gallium arsenide, and so on. Inorganic material substrates may be made of sapphire, ceramics, glass, and so on. Oxide wafers may be lithium tantalate wafers or lithium niobate wafers with or without devices formed thereon.

While the embodiments of the present Invention have been described, the above embodiments and modifications may be combined wholly or partly as other embodiments of the present invention.

The present invention is not limited to the embodiments and modifications described above, but many changes, replacements, and modifications may be made without departing from the scope of the present invention. Furthermore, the present invention may be reduced to practice according to other techniques, processes, schemes, plans, or arrangements insofar as they are capable of implementing the principles of the present invention owing to technological advances or derivations. Therefore, the scope of the appended claim should be interpreted as covering all the embodiments falling within the range of the technical idea of the present invention.

As described above, the cutting blade detecting mechanism for the cutting apparatus according to the present, invention determines the state of the shape of the tip end of the cutting edge based on the images of the outer periphery of the cutting edge that have been captured in the cutting feed direction, thereby making it possible to examine the state of the cutting blade highly accurately and quickly, and contributing to an increase in the processing capability and productivity of the cutting apparatus.

The present invention is not limited to the details of the above described preferred embodiments. The scope of the invention is defined by the appended claim and all changes and modifications as fall within the equivalence of the scope of the claim are therefore to be embraced by the invention.

What is claimed is:

1. A cutting blade detecting mechanism for use in a cutting apparatus including a chuck table for holding a workpiece thereon and cutting means including a cutting blade having an annular cutting edge for cutting the workpiece held on said chuck table while the workpiece is being cutting-fed in an X-axis direction, said cutting blade detecting mechanism having blade detecting means for detecting the state of said cutting edge of the cutting blade, wherein said blade detecting means comprises
an image capturing unit configured to capture an image of an outer periphery including an outer periphery end of said cutting edge in said X-axis direction;
a light emitter disposed in a position opposite said image capturing unit and facing said cutting edge; and
a decision unit configured to determine the state of the shape of a tip end of the cutting edge from the image of the outer periphery of the cutting edge which has been captured by said image capturing unit.
